(19) United States
(12) Patent Application Publication
(10) Pub. No.: US 2012/0063077 A1
(43) Pub. Date: Mar. 15, 2012

(54) HANDHELD TERMINAL DEVICE AND ELECTRONIC EQUIPMENT

(75) Inventors: Shinji Tomobe, Kanagawa (JP); Yasutoki Manda, Kanagawa (JP); Hidehiko Amaki, Kanagawa (JP); Takeshi Sekne, Kanagawa (JP); Takefumi Ishida, Kanagawa (JP)

(73) Assignee: PANASONIC CORPORATION, Osaka (JP)

(21) Appl. No.: 13/320,843

(22) PCT Filed: Apr. 15, 2010
(86) PCT No.: PCT/JP2010/002741

§ 371 Date: Nov. 16, 2011

(30) Foreign Application Priority Data
May 22, 2009 (JP) 2009-124598

(51) Int. Cl. H05K 5/06

(52) U.S. Cl. 361/679.01

(57) ABSTRACT

Provided is a handheld terminal device in which an excellent seal can be obtained without causing twisting, air bubbles, or gaps in double-sided tape. The handheld terminal device (100) has a water-resistant construction for a camera unit (113), a speaker unit (114), a charging terminal unit (116), a keypad (117), an antenna unit (118), a main display (121), and a sub-display (122). Said water-resistant construction comprises convex ribs having edge-shaped protrusions that press on water-resistant double-sided tape. For example, the sub-display (122) is provided with: a display unit (151) having a display opening (151a); a water-resistant wall (152) that is formed on the surface of the display unit (151) and has a convex rib (153); and water-resistant double-sided tape (154) that attaches the upper face of the water-resistant wall (152) having a convex rib (153) to the inner face of a sub-display exterior case (155).

### TECHNICAL FIELD

The present invention relates to a mobile terminal apparatus, such as a mobile telephone, and electronic equipment including these apparatuses. More particularly, the present invention relates to improvement of a waterproof structure of each member of a mobile terminal apparatus.

### BACKGROUND ART

With a housing of electronic equipment, such as a mobile telephone, it is preferable to be a waterproof structure that prevents, for example, rainwater from entering inside. A housing of electronic equipment is formed with, for example, a plastic front case and rear case, and is designed to waterproof by compressing the both cases in the direction of fitting in a state where a waterproof packing such as a rubber O-ring intervenes between the fitting surfaces of both cases. In addition, there is the method of preventing, for example, dust and moisture from entering inside by strongly pressing cases and predetermined members with a sealing material, such as rubber packing.

Patent literature 1 discloses the method of sealing equipment by making members adhere closely by using a tacky double-sided tape.

Patent literature 2 discloses a mobile terminal apparatus that has a waterproof structure around a key sheet to provide convex shaped limbs on a rubber key sheet, and also provide convex shaped limbs on an upper cover.

### CITATION LIST

### Patent Literature

PTL 1

Japanese Patent Application Laid-Open No.2003-209376

PTL 2

Japanese Patent Application Laid-Open No. 2000-151772

### SUMMARY OF INVENTION

### Technical Problem

With a conventional waterproof structure using a double-sided tape as above, sealing performance depends entirely on how properly the double-sided tape is applied. When the attachment is not enough due to, for example, twist of a double-sided tape, the sealing performance is extremely deteriorated and may not be able to keep waterproof property. Also, when attached, a double-sided tape easily produces air bubble and space, and may not be able to keep waterproof property. Particularly, with a double-sided tape used in a very narrow space, twist and space tends to be generated.

It is therefore an object of the present invention to provide a mobile terminal apparatus and electronic equipment that can acquire good airtightness without making, for example, twist, air bubble, or space in a double-sided tape.

### Solution to Problem

The mobile terminal apparatus and electronic equipment of the present invention include: the first member that has an opening section; the waterproof barrier that encircles the opening section of the first member; the second member that is pasted to the upper face of the waterproof barrier and seals space encircled by the waterproof barrier; and the waterproof double-sided tape that pastes the waterproof barrier and the second member, where the waterproof barrier has a convex shaped limb that projects to a waterproof double-sided tape side.

### ADVANTAGEOUS EFFECTS OF INVENTION

According to the present invention, it is possible to acquire good airtightness without making, for example, twist, air bubble, or space in a double-sided tape.

### BRIEF DESCRIPTION OF THE DRAWINGS

FIG. 1 is a perspective view of a mobile terminal apparatus according to an embodiment of the present invention;

FIG. 2 is an exploded perspective view showing a configuration of a sub display of a mobile terminal apparatus according to the present embodiment;

FIG. 3 is an exploded perspective view showing a configuration of a main display of a mobile terminal apparatus according to the present embodiment;

FIG. 4 is an exploded perspective view showing a configuration of a key operation section of a mobile terminal apparatus according to the present embodiment;

FIG. 5 is an exploded perspective view showing a configuration of a charging terminal section and a speaker section of the first housing of a mobile terminal apparatus according to the present embodiment;

FIG. 6 is an A-A′ line cross sectional view seen from the direction of the arrow of FIG. 5;

FIG. 7 is a B-B′ line cross sectional view seen from the direction of the arrow of FIG. 5;

FIG. 8 is an exploded perspective view showing a configuration of a camera section and an antenna section of the first housing of a mobile terminal apparatus according to the present embodiment;

FIG. 9 is an A-A′ line cross sectional view seen from the direction of the arrow of FIG. 8; and

FIG. 10 is a B-B′ line cross sectional view seen from the direction of the arrow of FIG. 8.

### DESCRIPTION OF EMBODIMENTS

Embodiment of the present invention will be explained in detail with reference to the accompanying drawings below.

### Embodiment

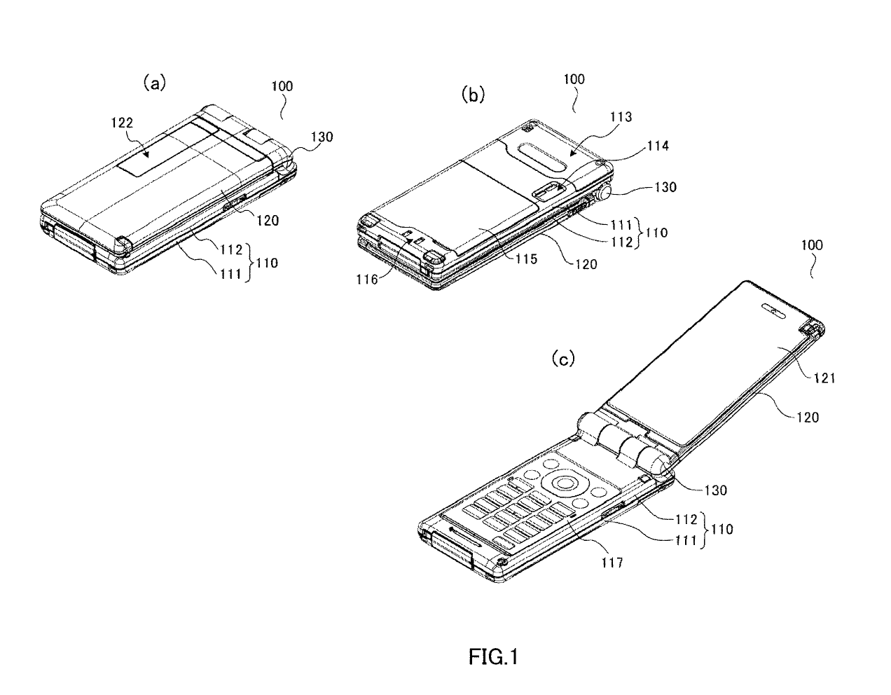

FIG. 1 is a perspective view of a mobile terminal apparatus according to an embodiment of the present invention; FIG. 1(a) is a perspective view showing a closed state seen from a front face of the mobile terminal apparatus; FIG. 1(b) is a perspective view showing a closed state seen from a back face of the mobile terminal apparatus; and FIG. 1(c) is a perspective view showing an open state seen from a back face of the mobile terminal apparatus. In the present description, “upward” means a perspective in which the front face of a mobile terminal apparatus is placed upward.

The present embodiment is an example applied to a flip mobile telephone/a personal handy-phone system (PHS) as a mobile terminal apparatus. In addition to a flip mobile telephone, it is possible to apply to mobile electronic equipment, for example, a personal digital assistants (PDA) and a portable game machine.

As shown in FIG. 1, mobile terminal apparatus 100 is formed with first housing 110 having, for example, key operation section 117, second housing 120 having an LCD display, and hinge section 130 connecting first housing 110 and second housing 120 to be able to open an close.

First housing 110 and second housing 120 are formed with a resin molding that is insulant, such as, a non-conductive ABS resin.

First housing 110 has rear case 111 that forms a back face of mobile terminal apparatus 100 and front case 112 that faces second housing 120 when folded. By fitting rear case 111 and front case 112, first housing 110, which is a flat cabinet, is formed.

Rear case 111 has camera section 113 in the upper part, speaker section 114 in the middle right side, battery cover 115 that accommodates a battery at the lower part, and charging terminal section 116 at the bottom. Camera section 113 and battery cover 115 are formed with a resin material that has the same color and provides the same texture as rear case 111.

Second housing 120 has main display 121 and sub display 122 that is provided on the outer surface. Main display 121 and sub display 122 are formed with a LCD display or an organic electro-luminescence (EL) display.

Features of the present embodiment includes a waterproof structure of each component inside of first housing 110 and second housing 120.

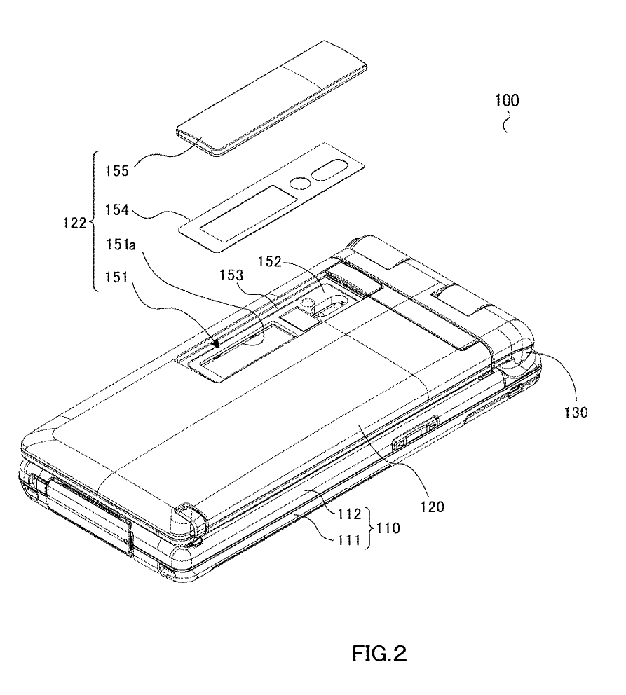

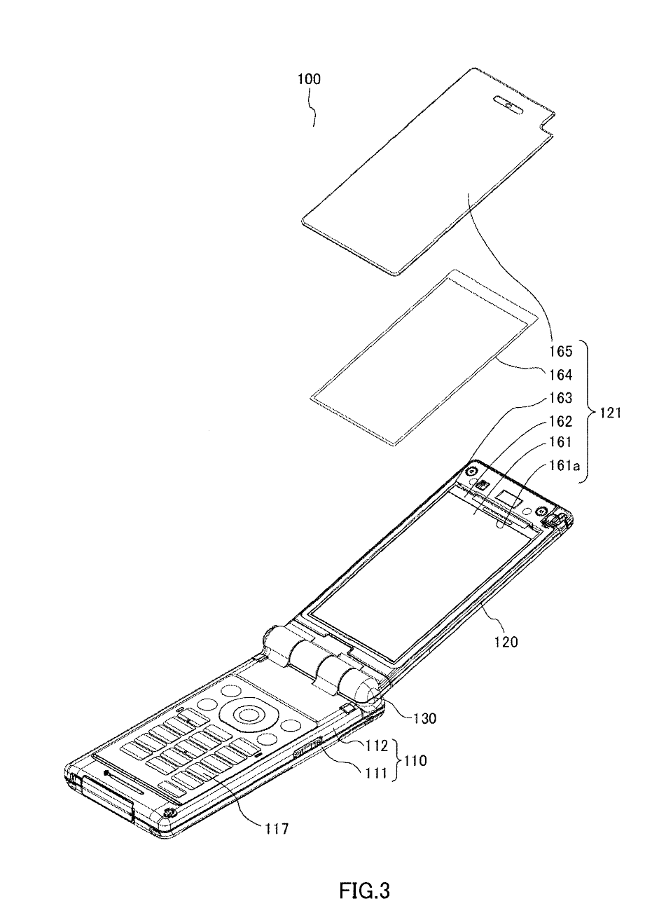

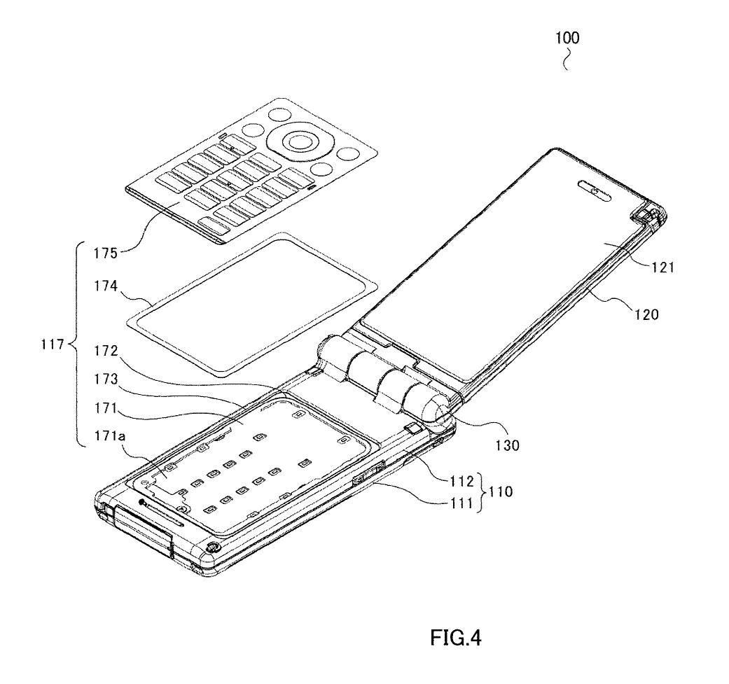

FIG. 2 is an exploded perspective view showing the structure of sub display 122 of above mobile terminal apparatus 100; FIG. 3 is an exploded perspective view showing the structure of main display 121 of above mobile terminal apparatus 100; and FIG. 4 is an exploded perspective view showing the structure of key operation section 117 of above mobile terminal apparatus 100.

[Waterproof structure of sub display 122]

As shown in FIG. 2, sub display 122 has display unit 151 having display opening section 151a, waterproof barrier 152 having convex shaped limb 153 formed on the front face of display unit 151, waterproof double-sided tape 154 adhering the inner face of sub display exterior case 155 and the upper face of waterproof barrier 152 that has convex shaped limb 153, and sub display exterior case 155.

Via waterproof double-sided tape 154, waterproof barrier 152 seals sub display exterior case 155 and the front face of display unit 151 where display opening section 1 51 a is open. Waterproof barrier 152 has a feature of having convex shaped limb 153 that projects to waterproof double-sided tape 154 side. Convex shaped limb 153 has a feature of encircling the surroundings including display opening section 151a. When convex shaped limb 153 is designed not to encircle, for example, display opening section 151a (that is, a discrete convex shaped projection), the sealing performance is diminished instead.

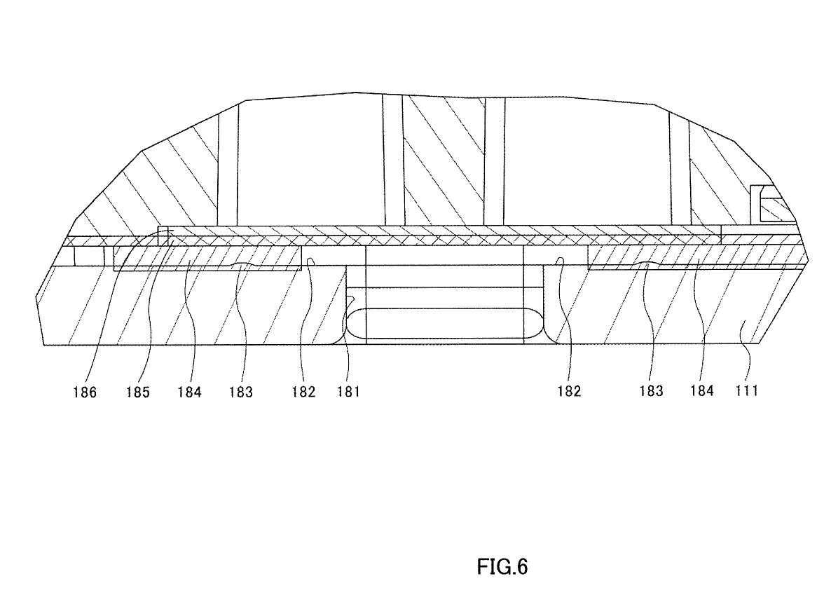

As long as convex shaped limb 153 is a convex shape, any shape is possible. However, if the convex shape is acute-angled as an apex of a triangle, waterproof double-sided tape 154 may be damaged when pushed or used for years, so that a curved face such as a semi-circular shape is preferable, as shown in FIG. 6 (described later). It is equally possible to be a triangle shape where the apexes are R-chamfered.

Convex shaped limb 153 only needs to encircle the surroundings of display opening section 151a, and at least one convex shaped limbs 153 is enough. It is equally possible to provide a plurality of convex shaped limbs 153 annularly.

Waterproof double-sided tape 154 is a double-stick, sheet-shaped sealing member. As shown in FIG. 2, waterproof double-sided tape 154 is punched out in advance to suit the shape of the front face to be sealed.

Sub display exterior case 155 is formed with transparent resin having a sense of coherence with the outer surface of second housing 120.

Next, the method of assembling sub display 122 will be described.

On the front face of display unit 151, waterproof barrier 152 having convex shaped limb 153 is formed.

On the upper face of waterproof barrier 152, waterproof double-sided tape 154 and sub display exterior case 155 are layered in order.

In this situation, sub display exterior case 155 is pressed from above. As a result of pressing force, the upper face of waterproof barrier 152 and the inner face of sub display exterior case 155 are stuck by waterproof double-sided tape 154.

The upper face of waterproof barrier 152 is stuck to the surface of waterproof double-sided tape 154 near entirely. In order to increase this adhesive force, convex shaped limb 153 presses waterproof double-sided tape 154 especially strong at the contacting point. Waterproof double-sided tape 154 receives a strong stress at the point where convex shaped limb 153 contacts, and strongly sticks to sub display exterior case 155 as slightly transforming. Sandwiched between convex shaped limb 153 and sub display exterior case 155, waterproof double-sided tape 154 is pressed with a strong force. As a result, waterproof double-sided tape 154 contacts more tightly, so that, by also increasing the stickiness of waterproof double-sided tape 154, it is possible to acquire good airtightness.

With convex shaped limb 153, since the shape of the convex part resolves negative factors, such as, twist, air bubble, and space of waterproof double-sided tape 154, reliable airtightness of sub display 122 is possible.

[Waterproof structure of main display 121]

As shown in FIG. 3, main display 121 has main display unit 161 that has display opening section 161a, waterproof barrier 162 that has convex shaped limb 163 formed on the front face of main display unit 161, waterproof double-sided tape 164 that sticks the inside of display panel 165 and the upper face of waterproof barrier 162 having convex shaped limb 163, and display panel 165 that is formed with transparent resin.

Via waterproof double-sided tape 164, waterproof barrier 162 seals display panel 165 and the front face of main display unit 161 where display opening section 161a is open. Waterproof barrier 162 has convex shaped limb 163 that projects to waterproof double-sided tape 164 side. Convex shaped limb 163 encircles the surroundings including display opening section 161a.

Waterproof double-sided tape 164 is a double-stick, sheet-shaped seal component. As shown in FIG. 3, waterproof double-sided tape 164 is punched out to suit the shape of display opening section 161a.

Next, the method of assembling main display 121 will be described.

On the front face of main display unit 161, waterproof barrier 162 having convex shaped limb 163 is formed.

On the upper face of waterproof barrier 162, waterproof double-sided tape 164 and display panel 165 are layered in order.

In this situation, display panel 165 is pressed from above. As a result of pressing force, the upper face of waterproof barrier 162 and the inner face of display panel 165 are stuck by waterproof double-sided tape 164.

The upper face of waterproof barrier 162 is stuck to the surface of waterproof double-sided tape 164 near entirely. Convex shaped limb 163 presses waterproof double-sided tape 164 especially strong at the contacting point. Waterproof double-sided tape 164 receives a strong stress at the point where convex shaped limb 163 contacts, and strongly sticks to display panel 165 as slightly transforming. Sandwiched between convex shaped limb 163 and display panel 165, waterproof double-sided tape 164 is pressed with a strong force. As a result, waterproof double-sided tape 164 contacts more tightly, so that. by also increasing the stickiness of waterproof double-sided tape 164, it is possible to acquire good airtightness in main display 121.

[Waterproof structure of key operation section 117]

As shown in FIG. 4, key operation section 117 has key sheet support substrate 171 that supports key sheet 171a that performs switching operation by pressing force that work key top 175, waterproof barrier 172 that has convex shaped limb 173 formed on the front face of key sheet support substrate 171, waterproof double-sided tape 174 that sticks the inner face of key top 175 and the upper face of waterproof barrier 172 having convex shaped limb 173, and key top 175 that has a keypad structure.

Via waterproof double-sided tape 174, waterproof barrier 172 seals key top 175 and the front face of key sheet support substrate 171 that supports key sheet 171a. Waterproof barrier 172 has convex shaped limb 173 that projects to waterproof double-sided tape 174 side.

Convex shaped limb 173 encircles the surroundings including key sheet 171a. As long as convex shaped limb 173 is a convex shape, any shape is possible.

Waterproof double-sided tape 174 is a double-stick, sheet-shaped seal component. As shown in FIG. 4, waterproof double-sided tape 174 is punched out in advance to suit the shape of key top 175 to be sealed.

In key top 175, keys are arranged in a matrix form. On the front face of key top 175, for example, symbols, letters, and numbers are formed corresponding to these keys by paint, plating, punch mark, or ion plating. On the back face of key top 175, an elastic material (not shown) that is a pushing element at the position corresponding to each key is strongly glued by a silicone adhesive.

Next, the method of assembling key operation section 117 will be described.

On the front face of key sheet support substrate 171, waterproof barrier 172 having convex shaped limb 173 is formed.

On the upper face of waterproof barrier 172, waterproof double-sided tape 174 and key top 175 are layered in order.

In this situation, key top 175 is pressed from above. As a result of pressing force, the upper face of waterproof barrier 172 and the bottom face of key top 175 are stuck by waterproof double-sided tape 174.

The upper face of waterproof barrier 172 is stuck to the surface of waterproof double-sided tape 174 near entirely. In order to increase this adhesive force, convex shaped limb 173 presses waterproof double-sided tape 174 especially strong at the contacting point. Waterproof double-sided tape 174 receives a strong stress at the point where convex shaped limb 173 contacts, and strongly sticks to key top 175 as slightly transforming. Sandwiched between convex shaped limb 173 and key top 175, waterproof double-sided tape 174 is pressed with a strong force. As a result, waterproof double-sided tape 174 contacts more tightly, so that, by also increasing the stickiness of waterproof double-sided tape 174, it is possible to acquire good airtightness.

With convex shaped limb 173, since the shape of the convex part resolves negative factors, such as, twist, air bubble, and space of waterproof double-sided tape 174, reliable airtightness of key operation section 117 is possible.

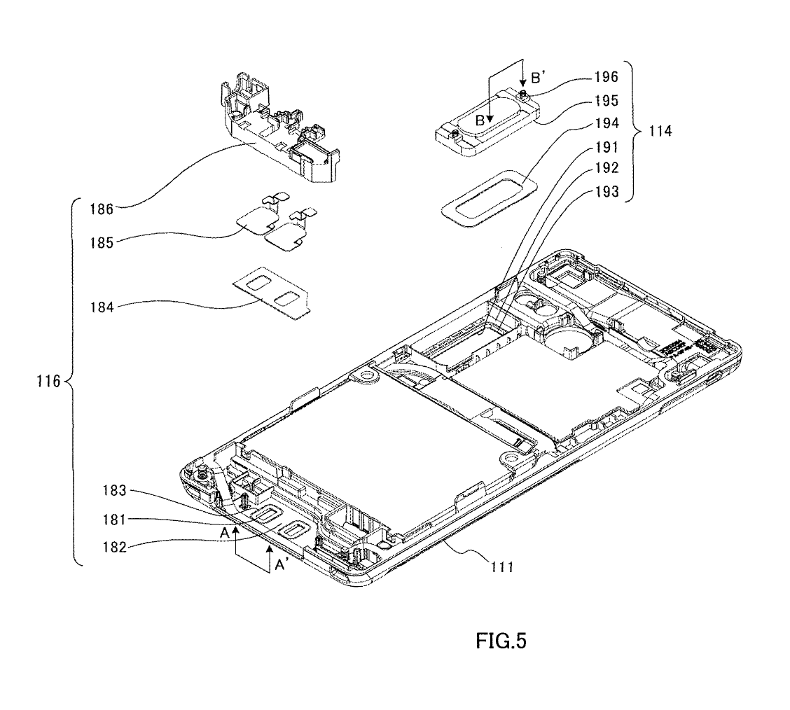

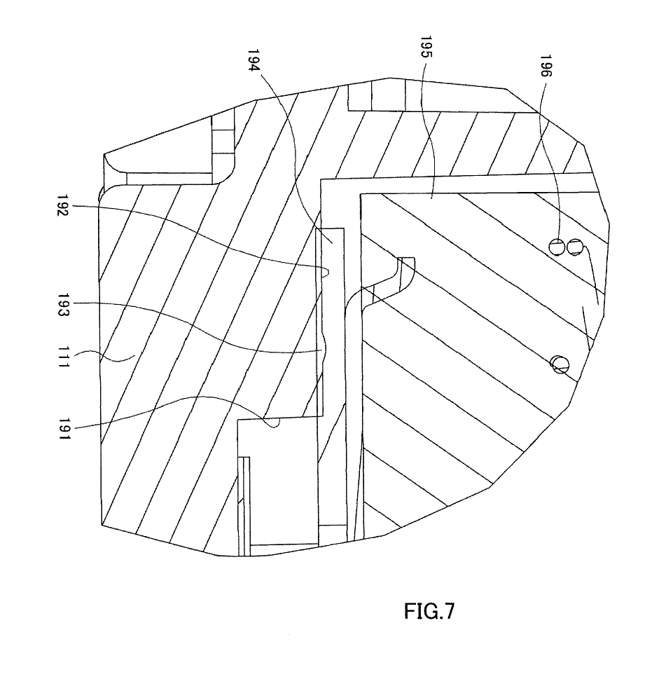

FIG. 5 is an exploded perspective view showing the structures of charging terminal section 116 and speaker section 114 of first housing 110 of the above mobile terminal apparatus 100. FIG. 5 further removes, for example, front case 112, key sheet support substrate 171, and hinge section 130 from first housing 110 of FIG. 4. FIG. 6 is an A-A′ line cross sectional view seen from the direction of the arrow of FIG. 5, and FIG. 7 is a B-B′ line cross sectional view seen from the direction of the arrow of FIG. 5.

[Waterproof structure of charging terminal section 116]

As shown in FIG. 5 and FIG. 6, charging terminal section 116 has charging terminal opening section 181 that is open in rear case 111 of first housing 110, waterproof barrier 182 that has convex shaped limb 183 formed on the back face of rear case 111, waterproof double-sided tape 184 that sticks electrode 185 and the upper face of waterproof barrier 182 having convex shaped limb 183, electrode 185 that connects to an external charging terminal (not shown), connector housing 186 that accommodates electrode 185.

Via waterproof double-sided tape 184, waterproof barrier 182 seals electrode 185 and the back face of rear case 111 where charging terminal opening section 181 is open. Waterproof barrier 182 has convex shaped limb 183 that projects to waterproof double-sided tape 184 side. As shown in FIG. 5, convex shaped limb 183 encircles the surroundings including charging terminal opening section 181.

As long as convex shaped limb 183 is a convex shape, any shape is possible. To prevent damage of waterproof double-sided tape 184 when pressed, a curved surface such as a semi-circular shape is preferable as shown in FIG. 6.

Waterproof double-sided tape 184 is a double-stick, sheet-shaped seal component. As shown in FIG. 5, waterproof double-sided tape 184 is punched out in advance to suit the shape of the front face to be sealed.

Next, the method of assembling charging terminal section 116 will be described.

On the bottom part of the back face of rear case 111, waterproof barrier 182 having convex shaped limb 183 is formed.

On the upper face of waterproof barrier 182, waterproof double-sided tape 184 and electrode 185 are layered in order.

In this situation, electrode 185 is pressed from above. As a result of pressing force, the upper face of waterproof barrier 182 and the inner face of electrode 185 are stuck by waterproof double-sided tape 184.

The back face of rear case 111, that is, the upper face of waterproof barrier 182 is stuck to the surface of waterproof double-sided tape 184 near entirely. In order to increase this adhesive force, convex shaped limb 183 presses waterproof double-sided tape 184 especially strong at the contacting point. Waterproof double-sided tape 184 receives a strong stress at the point where convex shaped limb 183 contacts, and strongly sticks to electrode 185 as slightly transforming. Sandwiched between convex shaped limb 183 and electrode 185, waterproof double-sided tape 184 is pressed with a strong force. As a result, waterproof double-sided tape 184 contacts more tightly, so that, by also increasing the stickiness of waterproof double-sided tape 184, it is possible to acquire good airtightness.

With convex shaped limb 183, since the shape of the convex part resolves negative factors, such as, twist, air bubble, and space of waterproof double-sided tape 184, reliable airtightness of charging terminal section 116 is possible.

[Waterproof structure of speaker section 114]

As shown in FIG. 5 and FIG. 7, speaker section 114 has speaker opening section 191 that is open in rear case 111 of first housing 110, waterproof barrier 192 that has convex shaped limb 193 formed on the back face of rear case 111, waterproof double-sided tape 194 that sticks speaker unit 195 and the upper face of waterproof barrier 192 having convex shaped limb 193, speaker unit 195, and spring 196 that is attached to speaker unit 195.

Via waterproof double-sided tape 194, waterproof barrier 192 seals speaker unit 195 and the back face of rear case 111 where speaker opening section 191 is open. Waterproof barrier 192 has convex shaped limb 193 that projects to waterproof double-sided tape 194 side.

As shown in FIG. 5, convex shaped limb 193 encircles the surroundings including speaker opening section 191.

As long as convex shaped limb 193 is a convex shape, any shape is possible. To prevent damage of waterproof double-sided tape 194 when pressed, a curved surface such as a semi-circular shape is preferable as shown in FIG. 7.

Waterproof double-sided tape 194 is a double-stick, sheet-shaped seal component. As shown in FIG. 5, waterproof double-sided tape 194 is punched out in advance to suit the shape of the front face to be sealed.

Next, the method of assembling speaker section 114 will be described.

On the back face of rear case 111, waterproof barrier 192 having convex shaped limb 193 is formed.

On the upper face of waterproof barrier 192, waterproof double-sided tape 194 and speaker unit 195 are layered in order.

In this situation, speaker unit 195 is pressed from above. As a result of pressing force, the upper face of waterproof barrier 192 and the inner face of speaker unit 195 are stuck by waterproof double-sided tape 194.

The back face of rear case 111, that is, the upper face of waterproof barrier 192 is stuck to the surface of waterproof double-sided tape 194 near entirely. In order to increase this adhesive force, convex shaped limb 193 presses waterproof double-sided tape 194 especially strong at the contacting point. Waterproof double-sided tape 194 receives a strong stress at the point where convex shaped limb 193 contacts, and strongly sticks to speaker unit 195 as slightly transforming. Sandwiched between convex shaped limb 193 and speaker unit 195, waterproof double-sided tape 194 is pressed with a strong force. As a result, waterproof double-sided tape 194 contacts more tightly, so that, by also increasing the stickiness of waterproof double-sided tape 194, it is possible to acquire good airtightness in speaker section 114.

With convex shaped limb 193, since the shape of the convex part resolves negative factors, such as, twist, air bubble, and space of waterproof double-sided tape 194, reliable airtightness is possible.

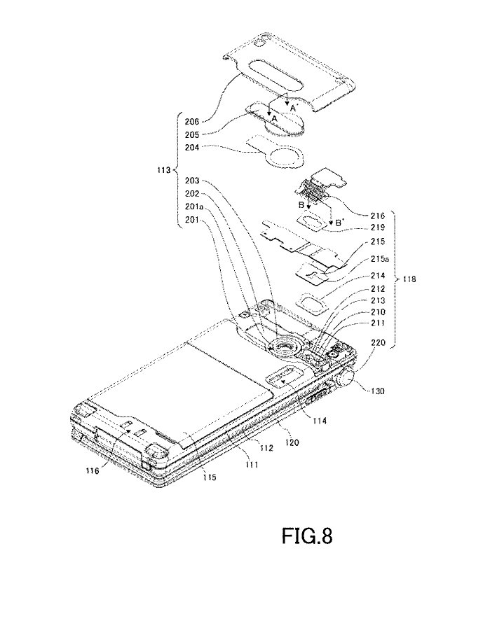

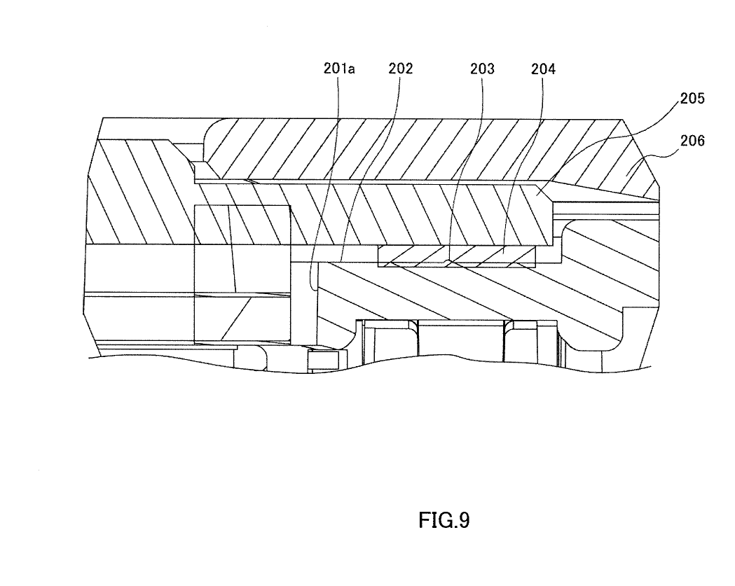

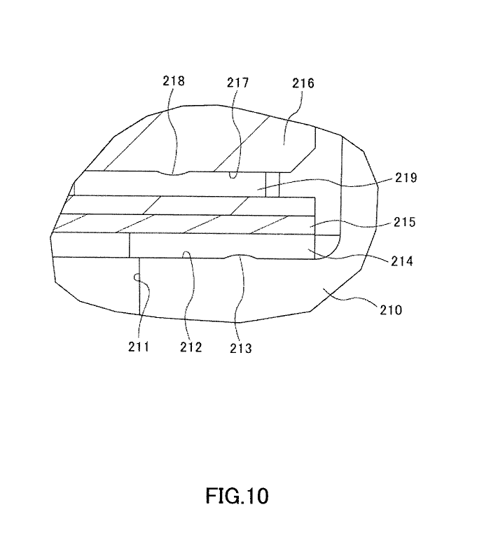

FIG. 8 is an exploded perspective view showing the structures of camera section 113 and antenna section 118 of first housing 110 of above mobile terminal apparatus 100. FIG. 8 removes a camera section exterior case from rear case 111 of first housing 110 of FIG. 1(b). FIG. 9 is an A-A′ line cross sectional view seen from the direction of the arrow of FIG. 8, and FIG. 10 is a B-B′ line cross sectional view seen from the direction of the arrow of FIG. 8.

[Waterproof structure of camera section 113]

As shown in FIG. 8 and FIG. 9, camera section 113 has camera unit 201 that has camera opening section 201a, waterproof barrier 202 that has convex shaped limb 203 formed on the front face of camera unit 201, waterproof double-sided tape 204 that sticks the outer peripheral surface of lens protective cap 205 and the upper face of waterproof barrier 202 having convex shaped limb 203, lens protective cap 205, and camera section exterior case 206.

Via waterproof double-sided tape 204, waterproof barrier 202 seals the outer peripheral surface of lens protective cap 205 and the front face of camera unit 201 where camera opening section 201a is open. Waterproof barrier 202 has convex shaped limb 203 that projects to waterproof double-sided tape 204 side. Convex shaped limb 203 encircles the surroundings including camera opening section 201a.

As long as convex shaped limb 203 is a convex shape, any shape is possible. To prevent damage of waterproof double-sided tape 204 when pressed, a curved surface such as a semi-circular shape is preferable as shown in FIG. 9. Convex shaped limb 203 only needs to encircle the surroundings of display opening section 201a, and at least one convex shaped limbs 203 is enough. It is equally possible to provide a plurality of convex shaped limbs 203 annularly.

Waterproof double-sided tape 204 is a double-stick, sheet-shaped seal component. As shown in FIG. 8, waterproof double-sided tape 204 is punched out in advance to suit the shape of the front face of camera unit 201 to be sealed.

Camera section exterior case 206 is formed with transparent resin having a sense of coherence with the outer surface of rear case 111 of first housing 110.

Next, the method of assembling camera section 113 will be described.

On the front face of camera unit 201, waterproof barrier 202 having convex shaped limb 203 is formed.

On the upper face of waterproof barrier 202, waterproof double-sided tape 204, lens protective cap 205, and camera section exterior case 206 are layered in order.

In this situation, camera section exterior case 206 is pressed from above. As a result of pressing force, the upper face of waterproof barrier 202 and the outer peripheral part of lens protective cap 205 are stuck by waterproof double-sided tape 204.

The upper face of waterproof barrier 202 is stuck to the surface of waterproof double-sided tape 204 near entirely. In order to increase this adhesive force, convex shaped limb 203 presses waterproof double-sided tape 204 especially strong at the contacting point. Waterproof double-sided tape 204 receives a strong stress at the point where convex shaped limb 203 contacts, and strongly sticks to camera section exterior case 206 as slightly transforming. Sandwiched between convex shaped limb 203 and the outer peripheral part of lens protective cap 205, waterproof double-sided tape 204 is pressed with a strong force. As a result, waterproof double-sided tape 204 contacts more tightly, so that, by also increasing the stickiness of waterproof double-sided tape 204, it is possible to acquire good airtightness.

With convex shaped limb 203, since the shape of the convex part resolves negative factors, such as, twist, air bubble, and space of waterproof double-sided tape 204, reliable airtightness of camera section 113 is possible.

[Waterproof structure of antenna section 118]

Antenna section 118 has a waterproof structure on front and back faces.

As shown in FIG. 8 and FIG. 10, antenna section 118 has power feeding terminal opening section 211 that is open in support substrate 210, waterproof barrier 212 that has convex shaped limb 213 formed on the front face of support substrate 210, first waterproof double-sided tape 214 that sticks the back face of antenna plate 215 and the upper face of waterproof barrier 212 having convex shaped limb 213, antenna plate 215 that has opening groove 215a, substrate 216 that mounts electronic components, waterproof barrier 217 (FIG. 10) that has convex shaped limb 218 (FIG. 10) formed on the back face of substrate 216, second waterproof double-sided tape 219 that sticks the upper face of antenna plate 215 and the upper face of waterproof barrier 217 having convex shaped limb 218.

Power feeding terminal 220 shows in power feeding terminal opening section 211 of support substrate 210 and is electrically connected with antenna plate 215 after assembling.

Via first waterproof double-sided tape 214, waterproof barrier 212 seals the back face of antenna plate 215 and the upper face of support substrate 210 where power feeding terminal opening section 211 is open. In the same way, via second waterproof double-sided tape 219, waterproof barrier 217 seals the back face of substrate 216 and the front face of antenna plate 215.

Waterproof barriers 212 and 217 both have convex shaped limbs 213 and 218 (FIG. 10) that are projected to waterproof double-sided tapes 214 and 219 sides. As shown in FIG. 8, convex shaped limbs 213 and 218 (FIG. 10) encircle the surroundings including power feeding terminal opening section 211 and opening groove 215a of antenna plate 215.

As shown in FIG. 10, convex shaped limbs 213 and 218 are arranged at the position where the front face and the back face of antenna plate 215 are not overlapped.

As long as convex shaped limbs 213 and 218 (FIG. 10) are convex shapes, any shape is possible. To prevent damage of waterproof double-sided tapes 214 and 219 when pressed, a curved surface such as a semi-circular shape is preferable as shown in FIG. 10.

Waterproof double-sided tapes 214 and 219 are double-stick, sheet-shaped seal components. As shown in FIG. 8, waterproof double-sided tapes 214 and 219 are punched out in advance to suit the shapes of the front faces to be sealed.

Next, the method of assembling antenna section 118 will be described.

On the front face of support substrate 210, waterproof barrier 212 having convex shaped limb 213 is formed. On the back face of substrate 216, waterproof barrier 217 (FIG. 10) having convex shaped limb 218 (FIG. 10) is formed.

On the upper face of waterproof barrier 212, first waterproof double-sided tape 214, antenna plate 215, second waterproof double-sided tape 219, and substrate 216 are layered in order.

In this situation, substrate 216 is pressed from above. As a result of pressing force, the upper face of waterproof barrier 212 and the back face of antenna plate 215, and the upper face of waterproof barrier 217 and the front face of antenna plate 215, are stuck by waterproof double-sided tapes 214 and 219 respectively.

Convex shaped limbs 213 and 218 (FIG. 10) press waterproof double-sided tapes 214 and 219 especially strong at the contacting points. Waterproof double-sided tapes 214 and 219 receive a strong stress at the point where convex shaped limbs 213 and 218 (FIG. 10) contact, and strongly stick to the front and back faces of antenna plate 215 as slightly transforming. Sandwiched between convex shaped limbs 213 and 218 (FIG. 10) and antenna plate 215, waterproof double-sided tapes 214 and 219 (FIG. 10) are pressed with strong forces. As a result, waterproof double-sided tapes 214 and 219 contact more tightly, so that, by also increasing the stickiness of waterproof double-sided tapes 214 and 219, it is possible to acquire good airtightness.

With convex shaped limbs 213 and 218 (FIG. 10), since the shape of the convex part resolves negative factors, such as, twist, air bubble, and space of waterproof double-sided tapes 214 and 219, reliable airtightness is possible.

In this way, in antenna section 118 that has waterproof structures on front and back faces, it is possible to acquire good airtightness.

As described above, according to the present embodiment, mobile terminal apparatus 100 has convex shaped limbs that press waterproof double-sided tapes by an edge shaped protrusion, as the waterproof structure of camera section 113, speaker section 114, charging terminal section 116, key operation section 117, antenna section 118, main display 121, and sub display 122. For example, sub display 122 has display unit 151 that has display opening section 151 a, waterproof barrier 152 that has convex shaped limb 153 formed on the front face of display unit 151, and waterproof double-sided tape 154 that sticks the inner face of sub display exterior case 155 and the upper face of waterproof barrier 152 having convex shaped limb 153. If sub display exterior case 155 is pressed from above upon assembling, the upper face of waterproof barrier 152 and the inner face of sub display exterior case 155 are stuck by waterproof double-sided tape 154, and at the same time, convex shaped limb 153 presses waterproof double-sided tape 154 especially strong at the apex part. As a result, waterproof double-sided tape 154 contacts more tightly, so that, by also increasing the stickiness of waterproof double-sided tape 154, it is possible to acquire good airtightness. The above functions are the same in camera section 113, speaker section 114, charging terminal section 116, key operation section 117, antenna section 118, and main display 121. In the present embodiment, it is possible to realize reliable waterproof property in each section.

Convex shaped limb 153 can prevent twist produced in waterproof double-sided tape 154 by the level of the convex part (projecting part). For the similar reason, convex shaped limb 153 can properly release air bubble and space produced in waterproof double-sided tape 154. By this means, reliable airtightness is possible.

Also, since waterproof double-sided tape 154 is used, there is an effect enabling to acquire good airtightness, even if the strength of cases and members is low or space is narrow, compared to the method of strongly pressing cases and predetermined members with a sealing material, such as rubber packing.

Therefore, it is possible to realize to make a mobile terminal apparatus smaller and thinner, acquiring sufficient waterproof structure.

The above description is an example, and the range of the present invention is not limited to this.

For example, although a convex shaped limb only needs to encircle the surroundings of an opening section and at least one convex shaped limb is enough, it is equally possible to provide a plurality of convex shaped limbs annularly.

Although camera section 113, speaker section 114, charging terminal section 116, key operation section 117, antenna section 118, main display 121, and sub display 122 have been exemplified as the waterproof structure of mobile terminal apparatus 100, it is possible to apply the same structure to other elements. Obviously, it is equally possible to apply to more than one of these elements.

Although in the above embodiment a case has been explained where the present invention is applied to apply to a mobile terminal of a mobile telephone as a mobile terminal apparatus, the present invention is not limited to a mobile telephone, and is equally possible to apply to a mobile information terminal, for example, PDA, a personal computer or a merged apparatus, and further a mobile device, such as, an MP3 player, an HDD player, or a mobile game machine.

Furthermore, although the term “mobile terminal apparatus” has been used for ease of explanation, a waterproof structure of electronic equipment and electronic equipment, such as mobile electronic equipment are equally possible.

Further, anything may be employed for the shape, material, the number and the method of attaching parts that forms the above mobile terminal apparatus, including the connection structure of a housing and a convex shaped limb. Also, a waterproof double-sided tape may be referred to as “double-sided adhesive tape,” “double-sided adhesive sheet,” or simply as “double-sided tape.”

The disclosure of Japanese Patent Application No. 2009-124598, filed on May 22, 2009, including the specification, drawings and abstract, is incorporated herein by reference in its entirety.

### INDUSTRIAL APPLICABILITY

A mobile terminal apparatus and electronic equipment according to the present invention is useful to use as a waterproof structure of a housing or an element of battery driven electronic equipment, such as, a mobile telephone. Also, a mobile terminal apparatus and electronic equipment according to the present invention are not limited to a housing or an element, and is equally possible to provide a waterproof structure of other housing or element to various electronic equipments.

### REFERENCE SIGNS LIST

100 Mobile terminal apparatus
110 First housing
111 Rear case
112 Front case
113 Camera section
114 Speaker section
115 Battery cover
116 Charging terminal section
117 Key operation section
118 Antenna section
120 Second housing
121 Main display
122 Sub display
130 Hinge section
151 Display unit
151a Display opening section
152, 162, 172, 182, 192, 202, 212, 217 Waterproof barrier
153, 163, 173, 183, 193, 203, 213, 218 Convex shaped limb
154, 164, 174, 184, 194, 204, 214, 219 Waterproof double-sided tape
155 Sub display exterior case
161 Main display unit
161a Display opening section
165 Display panel
171 Key sheet support substrate
171a Key sheet
175 Key top
181 Charging terminal opening section
185 Electrode
186 Connector housing
191 Speaker opening section
201 Camera unit
201a Camera opening section
205 Lens protective cap
206 Camera section exterior case
210 Support substrate
211 Power feeding terminal opening section
215 Antenna plate
215a Opening groove
216 Substrate

1-8. (canceled)

9. A mobile terminal apparatus comprising:
a first member that has an opening section;
a waterproof barrier that encircles the opening section of the first member;
a second member that is pasted to an upper face of the waterproof barrier and seals space encircled by the waterproof barrier; and
a waterproof double-sided tape that pastes the waterproof barrier and the second member,
wherein the waterproof barrier has a convex shaped limb that projects to a waterproof double-sided tape side.

10. The mobile terminal apparatus according to claim 9, wherein the waterproof double-sided tape is pressed, sandwiched between the convex shaped limb and the second member.

11. The mobile terminal apparatus according to claim 9, wherein, in the convex shaped limb, a cross section shape that is perpendicular to a projecting direction is one of a triangle shape or a triangle shape that is R-chamfered at apexes.

12. The mobile terminal apparatus according to claim 9, wherein the convex shaped limb is integrally molded with a front face of the first member.

13. The mobile terminal apparatus according to claim 9, wherein the convex shaped limb is formed annularly near a center of the waterproof barrier surrounding the opening section.

14. The mobile terminal apparatus according to claim 9, wherein the first member and the second member are cases of a housing.

15. The mobile terminal apparatus according to claim 9, wherein the first member and the second member are one of a display panel unit, a camera unit, a keyboard unit, a speaker unit, an antenna unit, or a charging terminal section.

16. Electronic equipment comprising:
a first member that has an opening section;
a waterproof barrier that encircles the opening section of the first member;
a second member that is pasted to an upper face of the waterproof barrier and seals space encircled by the waterproof barrier; and
a waterproof double-sided tape that pastes the waterproof barrier and the second member,
wherein the waterproof barrier has a convex shaped limb that projects to a waterproof double-sided tape side.
